(19) United States
(12) Patent Application Publication
(10) Pub. No.: US 2010/0263721 A1
(43) Pub. Date: Oct. 21, 2010

(54) TRANSPARENT SOLAR CELL

(75) Inventors: JungWook LIM, Daejeon (KR); Sun Jin YUN, Daejeon (KR); Seong Hyun LEE, Busan (KR); Je Ha KIM, Daejeon (KR)

Correspondence Address: RABIN & Berdo, PC, 1101 14TH STREET, NW, SUITE 500, WASHINGTON, DC, 20005, US

(73) Assignee: ELECTRONICS AND TELECOMMUNICATIONS RESEARCH INSTITUTE, Daejeon (KR)

(21) Appl. No.: 12/684,768

(22) Filed: Jan. 8, 2010

(30) Foreign Application Priority Data
Apr. 20, 2009 (KR) 10-2009-0034159
Jun. 19, 2009 (KR) 10-2009-0055025

(51) Int. Cl. H01L 31/00

(52) U.S. Cl. 136/256

(57) ABSTRACT

Provided is a transparent solar cell. The transparent solar cell includes a transparent substrate, a selective transparent reflection layer, a first electrode, a photovoltaic conversion layer and a second electrode. The selective transparent reflection layer includes a first surface contacting the transparent substrate, and the second surface facing the first surface. The first electrode, the photovoltaic conversion layer and the second electrode are sequentially stacked on the second surface of the selective transparent reflection layer. The selective transparent reflection layer transmits at least a portion of wavelength of a visible ray and reflects an infrared ray.

### CROSS-REFERENCE TO RELATED APPLICATIONS

This U.S. non-provisional patent application claims priority under 35 U.S.C. §119 of Korean Patent Application Nos. 10-2009-0034159, filed on Apr. 20, 2009, and 10-2009-0055025, filed on Jun. 19, 2009, the entire contents of which are hereby incorporated by reference.

### BACKGROUND OF THE INVENTION

The present invention disclosed herein relates to a solar cell, and more particularly, to a transparent solar cell.

A solar cell is a photovoltaic energy conversion system for converting light radiated from the sun into electric energy. In a silicon solar cell, electron-hole pairs are generated in a semiconductor, by incident light, whereupon the electrons move to an N-type semiconductor and the holes move to a P-type semiconductor by means of an electric field produced at a P-N junction, generating power.

Because solar cells produce power using the sun as an infinite source of light energy and do not contribute to environmental pollution in producing power, they are widely regarded as a promising environment-friendly energy source for the future. Because photovoltaic energy conversion efficiency remains low, however, practical applications of solar cells involve many difficulties. Therefore, much research is underway to increase photovoltaic energy conversion efficiency in order to give solar cells greater utility.

### SUMMARY OF THE INVENTION

The present invention provides a transparent solar cell, which increases photovoltaic energy conversion efficiency.

The present invention also provides a transparent solar cell, which increases photovoltaic energy conversion efficiency and improves transparency.

The present invention also provides a transparent solar cell, which has various colors.

Embodiments of the present invention provide a transparent solar cell including: a transparent substrate; a selective transparent reflection layer including a first surface contacting the transparent substrate, and a second surface facing the first surface; and a first electrode, a photovoltaic conversion layer and a second electrode which are sequentially stacked on the second surface of the selective transparent reflection layer, wherein the selective transparent reflection layer transmits at least a portion of wavelength of visible ray and reflects an infrared ray.

In some embodiments, the transparent solar cell may further include a transparent anti-reflection layer on the second electrode.

In other embodiments, the transparent solar cell may further include: an addition selective transparent reflection layer between the first electrode and the photovoltaic conversion layer; an addition transparent anti-reflection layer between the second electrode and the photovoltaic conversion layer; a first plug connecting the first electrode and the photovoltaic conversion layer through the addition selective transparent reflection layer; and a second plug connecting the second electrode and the photovoltaic conversion layer through the addition transparent anti-reflection layer.

In still other embodiments, a refraction index of the transparent anti-reflection layer may be less than a refraction index of the second electrode, a refraction index of the second electrode may be less than a refraction index of the addition transparent anti-reflection layer, a refraction index of the addition selective transparent reflection layer may be less than a refraction index of the first electrode, and a refraction index of the first electrode may be less than a minimum refraction index of the selective transparent reflection layer.

In even other embodiments, a refraction index of the selective transparent reflection layer may vary in a direction from the first surface to the second surface.

In yet other embodiments, a refraction index of the selective transparent reflection layer may decrease in a direction from the first surface to the second surface.

In further embodiments, the selective transparent reflection layer may include a plurality of first and second selective transparent reflection layers which are alternately stacked, and a refraction index of the first selective transparent reflection layer may differ from a refraction index of the second selective transparent reflection layer.

In still further embodiments, the first selective transparent reflection layer which is most adjacent to the transparent substrate may contact the transparent substrate, the second selective transparent reflection layer which is most adjacent to the first electrode may contact the first electrode, and a refraction index of the first selective transparent reflection layer may be greater than a refraction index of the second selective transparent reflection layer.

In even further embodiments, the transparent solar cell may further include a burial selective transparent reflection layer burying a plurality of grooves which are disposed at the second surface of the selective transparent reflection layer.

In yet further embodiments, a minimum refraction index of the selective transparent reflection layer may be greater than a refraction index of the burial selective transparent reflection layer.

In still other embodiments, the photovoltaic conversion layer may include a fine crystal silicon layer.

In even other embodiments, the photovoltaic conversion layer may further include an amorphous silicon layer.

In yet other embodiments, the first electrode may include resistance-improving materials which are dotted in the first electrode, the second electrode may include resistance-improving materials which are dotted in the second electrode, and a conductivity of the resistance-improving material may be greater than conductivities of the first and second electrodes.

In further embodiments, the selective transparent reflection layer and the transparent anti-reflection layer may be formed by any one of Atomic Layer Deposition (ALD), Chemical Vapor Deposition (CVD), Physical Vapor Deposition (PVD), Pulse Laser Deposition (PLD) and Sol-Gel processes.

In still further embodiments, a transmittance of a visible ray having a first wavelength region of the selective transparent reflection layer may be greater than a transmittance of a visible ray having a second wavelength region of the selective transparent reflection layer.

In even further embodiments, an optical thickness of the selective transparent reflection layer may be about 40 nm to about 10,000 nm.

### BRIEF DESCRIPTION OF THE FIGURES

The accompanying figures are included to provide a further understanding of the present invention, and are incorporated in and constitute a part of this specification. The drawings illustrate exemplary embodiments of the present invention and, together with the description, serve to explain principles of the present invention. In the figures:

FIG. 1 is a cross-sectional view illustrating a transparent solar cell according to an embodiment of the present invention;

FIG. 2 is a cross-sectional view illustrating a transparent solar cell according to another embodiment of the present invention;

FIG. 3 is a graph illustrating absorption rates in accordance with the wavelength of light in a fine crystal silicon layer and an amorphous silicon layer;

FIG. 4 is a cross-sectional view illustrating a photovoltaic conversion layer according to an embodiment of the present invention;

FIG. 5 is a graph illustrating the relationship between the number of layers constituting the selective transparent reflection layer and the width of the wavelength band of light which is reflected by the selective transparent reflection layer;

FIG. 6 is a cross-sectional view illustrating a selective transparent reflection layer according to an embodiment of the present invention;

FIG. 7 is a cross-sectional view illustrating a selective transparent reflection layer according to another embodiment of the present invention;

FIGS. 8A and 8B are cross-sectional views illustrating a method for forming a transparent solar cell according to an embodiment of the present invention;

FIGS. 9A and 9B are cross-sectional views illustrating a method for forming a transparent solar cell according to another embodiment of the present invention;

FIG. 10 is a diagram illustrating a solar cell array using transparent solar cells according to embodiments of the present invention; and

FIG. 11 is a diagram illustrating an example of a photovoltaic system with transparent solar cells according to embodiments of the present invention.

### DETAILED DESCRIPTION OF PREFERRED EMBODIMENTS

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Since preferred embodiments are provided below, the order of the reference numerals given in the description is not limited thereto. In the figures, the dimensions of layers and regions are exaggerated for clarity of illustration. Also, it will be understood that when a layer (or film) is referred to as being ‘on’ another layer or substrate, it can be directly on the other layer or substrate, or intervening layers may also be present. In the specification, the term ‘and/or’ is used as meaning in which the term includes at least one of preceding and succeeding elements.

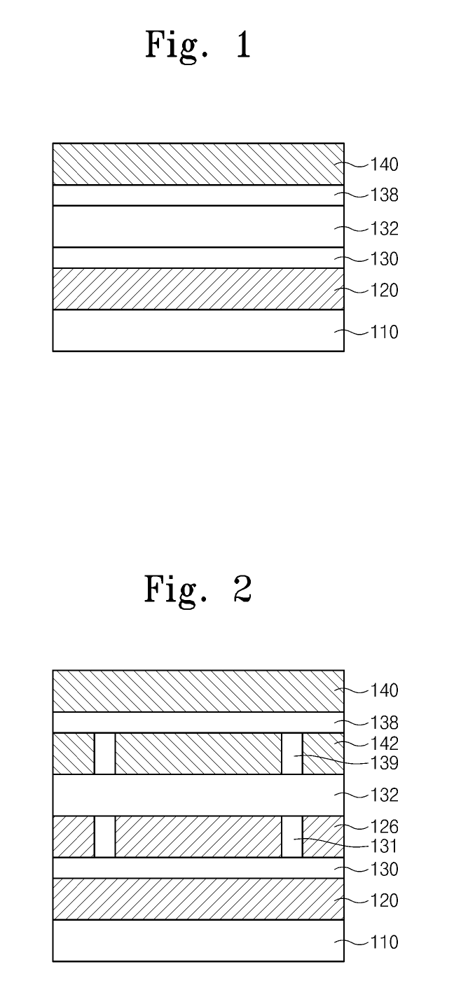

FIG. 1 is a cross-sectional view illustrating a transparent solar cell according to an embodiment of the present invention.

Referring to FIG. 1, a transparent substrate 110 is provided. A selective transparent reflection layer 120 may be disposed on the transparent substrate 110. The selective transparent reflection layer 120 may include a first surface contacting the transparent substrate 110, and a second surface facing the first surface. The selective transparent reflection layer 120 may transmit at least a portion of wavelength of visible rays and reflect infrared rays. A first electrode 130 may be disposed on the second surface of the selective transparent reflection layer 120. A second electrode 138 may be disposed on the first electrode 130. A photovoltaic conversion layer 132 may be interposed between the first and second electrodes 130 and 138. Accordingly, the first electrode 130, the photovoltaic conversion layer 132 and the second electrode 139 that are sequentially disposed and stacked on the second surface of the selective transparent reflection layer 120. A transparent anti-reflection layer 140 may be disposed on the second electrode 138.

The term transparency has a dictionary definition in which an object well transmits light. The degree of transparency of each object may be represented as transparency. Transparency (or transmittance) may be defined as the degree of transparency of each object, i.e., a value of the amount of light (which passes through medium) divided by the amount of light that is incident on the medium. In specification, the term transparency may be used in a case where a degree of transparency is about 100% and may be used in a case having a degree of transparency less than 100%.

The transparent anti-reflection layer 140 may include a light receiving surface. Solar light may be irradiated on the light receiving surface. The solar light, which is irradiated on the light receiving surface of the transparent anti-reflection layer 140, may pass through the transparent anti-reflection layer 140. For example, transmittance for light incident on the transparent anti-reflection layer 140 may be about 60% to about 90%. The light receiving surface of the transparent anti-reflection layer 140 may be textured to have a concave-convex structure. The concave-convex structure may include an inverted pyramid pattern that is regularly arranged. Consequently, in the light receiving surface of the transparent anti-reflection layer 140, reflection of solar light may be minimized. The transparent anti-reflection layer 140 may include at least one of aluminum titanium oxide, silicon titanium oxide, aluminum zirconium oxide, zirconium titanium oxide, hafnium titanium oxide, zirconium oxide, titanium oxide, hafnium oxide, aluminum oxide, silicon oxide and nitride silicon oxide.

Solar light incident on the second electrode 138 may pass through the second electrode 138. For example, transmittance of the second electrode 138 may be about 80% to about 90%. The second electrode 138 may include a transparent conductive material. For example, the transparent conductive material may include ZnO:Al, ZnO:Ga, ITO, SnO₂, SnO:F, RuO₂, IrO₂, and Cu₂O. The second electrode 138 may further include resistance-improving materials. The resistance-improving materials may be dotted in the second electrode 138. The conductivity of the resistance-improving material may be higher than that of the transparent electrode. For example, the resistance-improving material may include aluminum, platinum, molybdenum, argentum, aurum, titanium, nitride titanium, tantalum, nitride tantalum, nickel, copper, plumbum, zinc, cobalt, stannum and graphite. The resistance of the second electrode 138 can decrease by the resistance-improving material. Accordingly, in the second electrode 138, loss of electric energy can decrease, and efficiency of the transparent solar cell can improve. Moreover, the transparency of the transparent solar cell can be controlled according to the amount of the resistance-improving materials that are dotted in the second electrode 138.

Solar light passing through the second electrode 138 may transferred to the photovoltaic conversing layer 132. The photovoltaic conversion layer 132 may include a first conductive layer and a second conductive layer. The first conductive layer may be an N-type layer, and the second conductive layer may be a P-type layer. For example, the first conductive layer may include a material that is doped by group V elements such as phosphorus (P), arsenic (As) and stibium (Sb). The second conductive layer may include a material that is doped by group III elements such as boron (B), gallium (Ga) and indium (In). P-N junction may be formed between the first and second conductive layers. On the other hand, a layer on which impurities are not doped may be interposed between the first and second conductive layers.

Solar light that is transferred to the photovoltaic conversion layer 132 may produce carriers (for example, electrons or holes). The carriers (for example, electrons or holes) may be moved to the first and second conductive layers by an electric field that is produced in the P-N junction. For example, electrons may be moved to an N-type layer, and holes may be moved to a P-type layer. The electrons and the holes, which are respectively moved to the N-type layer and the P-type layer, may be transferred to an electronic device (not shown) through the first and second electrodes, thereby providing electric energy.

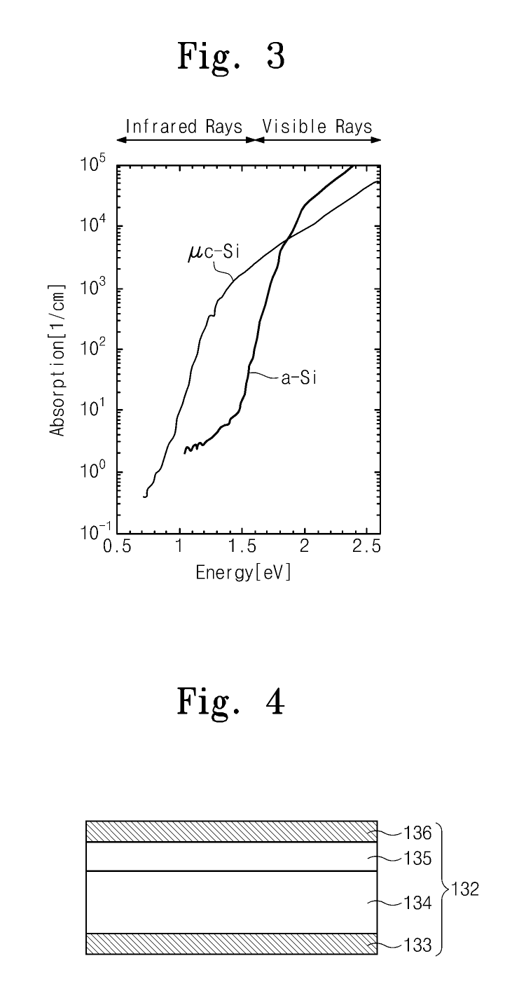

The photovoltaic conversion layer 132 may be a single layer or multi layers. The photovoltaic conversion layer 132 may include at least one of a fine crystal silicon layer and an amorphous silicon layer. The fine crystal silicon layer and the amorphous silicon layer may have different absorption rates according to the wavelength of incident light. Absorption rates in accordance with the wavelength of light in the fine crystal silicon layer the amorphous silicon layer will be describe below with reference to a graph in FIG. 3.

FIG. 3 is a graph illustrating absorption rates in accordance with the wavelength of light in the fine crystal silicon layer and the amorphous silicon layer.

Referring to FIG. 3, in an absorption rate for light of the wavelength of an infrared region, the absorption rate of the fine crystal silicon layer is higher than that of the amorphous silicon layer. On the other hand, in an absorption rate for light of the wavelength of a visible region, the absorption rate of the amorphous silicon layer is higher than that of the fine crystal silicon layer. Accordingly, in transmittance for light of the wavelength of the visible region, transmittance of the fine crystal silicon layer is higher than that of amorphous silicon layer. For securing enough transparency, therefore, using the fine crystal silicon layer as the photovoltaic conversion layer 132 may be better than using the amorphous silicon layer as the photovoltaic conversion layer 132. In the transparent solar cell according to an embodiment of the present invention, the photovoltaic conversion layer 132 may include the fine crystal silicon layer for securing enough transparency. To the contrary, as described above, the photovoltaic conversion layer 132 may include the fine crystal silicon layer and the amorphous silicon layer. In this case, because the absorption rate of the amorphous silicon layer is higher than that of the fine crystal silicon layer in an absorption rate for light of the wavelength of the visible region, the photovoltaic energy conversion efficiency of the transparent solar cell can improve. For improving the photovoltaic energy conversion efficiency of the transparent solar cell, the photovoltaic conversion layer 132 including the amorphous silicon layer will be described below with reference to FIG. 4.

FIG. 4 is a cross-sectional view illustrating the photovoltaic conversion layer according to an embodiment of the present invention.

Referring to FIG. 4, the photovoltaic conversion layer 132 may include a first conductive layer 133, and a first photovoltaic conversion layer 134, a second photovoltaic conversion layer 135 and a second conductive layer 136 which are sequentially stacked on the first conductive layer 133. The first conductive layer 133 may be an N-type layer, and the second conductive layer 136 may be a P-type layer. The first photovoltaic conversion layer 134 may be a fine crystal silicon layer, and the second photovoltaic conversion layer 135 may be an amorphous silicon layer. The first and second photovoltaic conversion layers 134 and 135 may be undoped layers. The photovoltaic conversion layer 132 includes the amorphous silicon layer, and thus the photovoltaic energy conversion efficiency of the transparent solar cell can improve.

By controlling the thickness of the photovoltaic conversion layer 132, transparency of the transparent solar cell may be controlled. For example, the photovoltaic conversion layer 132 may include a fine crystal silicon layer and/or an amorphous silicon layer. As described above, in an absorption rate for the wavelength of light of a visible region, the absorption rate of the amorphous silicon layer is higher than that of the fine crystal silicon layer. Accordingly, the transparency of the transparent solar cell may be more sensitively controlled according to the thickness of the amorphous silicon layer than that of the fine crystal silicon layer. For increasing transparency, the photovoltaic conversion layer 132 may have a thin-film type. The photovoltaic conversion layer 132 may have a thickness of several μm.

The unabsorbed solar light of solar lights that are incident on the photovoltaic conversion layer 132 may pass through the photovoltaic conversion layer 132. For example, when the photovoltaic conversion layer 132 includes a fine crystal silicon layer, the transmittance of the photovoltaic conversion layer 132 for visible rays may be about 5% to about 70%.

Solar light passing through the photovoltaic conversion layer 132 may be transferred to the first electrode 130. Solar light that is incident on the first electrode 130 may pass through the first electrode. For example, transmittance of the first electrode 130 may be about 80% to about 90%. The first electrode 130 may include a transparent conductive material. For example, the transparent conductive material may include ZnO:Al, ZnO:Ga, ITO, SnO₂, SnO:F, RuO₂, IrO₂, and Cu₂O. The first electrode 130 may further include resistance-improving materials. The resistance-improving materials may be dotted in the first electrode 130. The conductivity of the resistance-improving material may be higher than that of the first electrode 130. For example, the resistance-improving material may include aluminum, platinum, molybdenum, argentum, aurum, titanium, nitride titanium, tantalum, nitride tantalum, nickel, copper, plumbum, zinc, cobalt, stannum and graphite. Consequently, the resistance of the first electrode 130 can decrease. In the first electrode 130, therefore, loss of electric energy can decrease, and efficiency of the transparent solar cell can improve. The resistance-improving material may be opaque. Accordingly, the transparency of the transparent solar cell can be controlled according to the resistance-improving materials that are dotted in the first electrode 130.

Solar light passing through the first electrode 130 may be incident on the selective transparent reflection layer 120. A reflection rate for light of wavelength corresponding to the specific region of the selective transparent reflection layer 120 may be higher than a reflection rate for light of wavelength corresponding to other regions. Light of wavelength having a low reflection rate may have high transmittance for the selective transparent reflection layer 120. In the selective transparent reflection layer 120, a wavelength region having a high reflection rate is referred to as a reflection wavelength region, and a wavelength region having a high transmission rate is referred to as a transmission wavelength region. For example, the reflection wavelength region may be an infrared region. The reflection rate of the selective transparent reflection layer 120 for an infrared region may be about 10% to about 90%. Infrared rays reflected from the selective transparent reflection layer 120 may be reincident on the photovoltaic conversion layer 132. The photovoltaic energy conversion efficiency of the transparent solar cell can increase by the reincident infrared rays. Accordingly, a high absorption rate for light of the infrared region of the photovoltaic conversion layer 132 may be good for improvement of photovoltaic energy conversion efficiency. Accordingly, as described above, the photovoltaic conversion layer 132 may include a fine crystal silicon layer. The transmission wavelength region may be at least one portion of a visible region. The transmittance of the selective transparent reflection layer 120 for visible rays may be about 5% to about 70%. Accordingly, the high transparency of the transparent solar cell can be obtained.

The reflection wavelength region and the transmission wavelength region may be controlled according to the optical thickness of the selective transparent reflection layer 120. The optical thickness may be expressed as the multiplication of the physical thickness of medium and the refraction index of the medium. The refraction index of the selective transparent reflection layer 120 may be varied according to the composition ratio of materials constituting the selective transparent reflection layer 120. For example, when the selective transparent reflection layer 120 includes aluminum titanium oxide, the refraction index of the selective transparent reflection layer 120 may be controlled according to the composition ratio (aluminum:titanium:oxygen) of elements. The composition ratio of materials constituting the selective transparent reflection layer 120 and the thickness of the selective transparent reflection layer 120 may be controlled in the formation process of the selective transparent reflection layer 120. The optical thickness of the selective transparent reflection layer 120 may be controlled to transmit at least a portion of wavelength of the visible rays and to reflect infrared rays. For example, the optical thickness of the selective transparent reflection layer 120 may be about 400 nm to about 1000 nm.

The selective transparent reflection layer 120 may reflect a portion of the wavelength region of visible rays. For example, the transmission wavelength region of the selective transparent reflection layer 120 may be the first wavelength region of a visible region, and a reflection wavelength region may be the second wavelength region of the visible region. Consequently, light of the first wavelength region may pass through the transparent solar cell via the selective transparent reflection layer 120. On the other hand, light of the second wavelength region may be reflected and be thereby absorbed into the photovoltaic conversion layer 132. Accordingly, light passing through the transparent solar cell may have a specific color. Moreover, when the first wavelength region of the selective transparent reflection layer 120 is changed, the color of light passing through the transparent solar cell may be changed.

The selective transparent reflection layer 120 may have the change of a refraction index based on position movement from the first surface contacting the transparent substrate 110 to the second surface facing the first surface. For example, as a position is moved from the first surface to the second surface, the refraction index of the selective transparent reflection layer 120 may decrease. Consequently, transmittance for light of the transmission wavelength region of the selective transparent reflection layer 120 can increase. As an example, the selective transparent reflection layer 120 may relatively better transmit light of a visible region. Therefore, the transparency of the transparent solar cell can increase. With change of the refraction index, the selective transparent reflection layer 120 may have the minimum refraction index and the maximum refraction index.

To the contrary, the entirety of the selective transparent reflection layer 120 may have a conformal refraction index. In this case, the minimum refraction index of the selective transparent reflection layer 120 may be identical to the maximum refraction index of the selective transparent reflection layer 120.

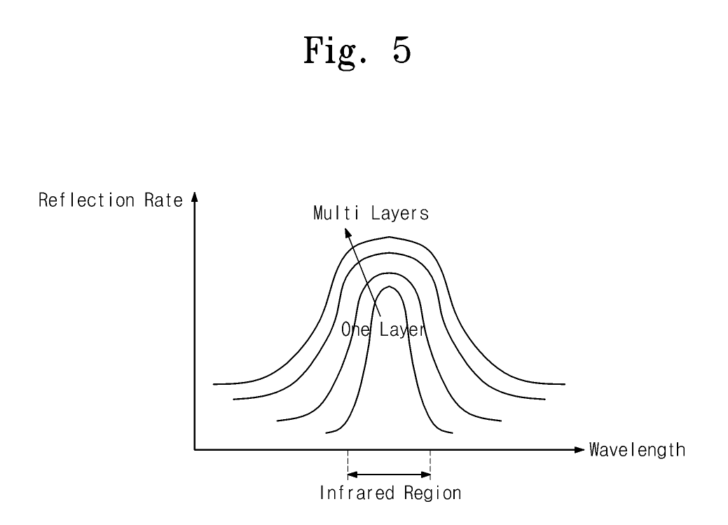

The selective transparent reflection layer 120 may be a single layer or multi layers. Depending on whether the selective transparent reflection layer 120 is a single layer or multi layers, the width of the reflection wavelength region may vary. The change of the width of the reflection wavelength region based on a plurality of layers, which are included in the selective transparent reflection layer 120, will be described below with reference to FIG. 5.

FIG. 5 is a graph illustrating the relationship between the number of layers constituting the selective transparent reflection layer and the width of the wavelength band of light which is reflected by the selective transparent reflection layer. This is a case where the reflection wavelength region of the selective transparent reflection layer corresponds to an infrared region.

Referring to FIG. 5, as described above, the selective transparent reflection layer 120 may include a single layer or a plurality of layers. When the selective transparent reflection layer 120 is a single layer, the width of the reflection wavelength region is narrow. On the other hand, as the selective transparent reflection layer 120 includes a plurality of layers and the number of the layers increases, the width of the reflection wavelength region becomes broader. When the width of the reflection wavelength region becomes broader, the amount of light (for example, infrared rays) that is reflected by the selective transparent reflection layer 120 may increase. Light (for example, infrared rays) of the reflection wavelength region may be absorbed into the photovoltaic conversion layer 132 and be converted into electric energy. Accordingly, as the selective transparent reflection layer 120 includes a plurality of layers, the photovoltaic energy conversion efficiency of the transparent solar cell may increase. On the contrary, when the width of the reflection wavelength region becomes narrower, the amount of light (for example, visible rays) of the transmission wavelength region may increase. Consequently, the transparent solar cell can have relatively higher transparency.

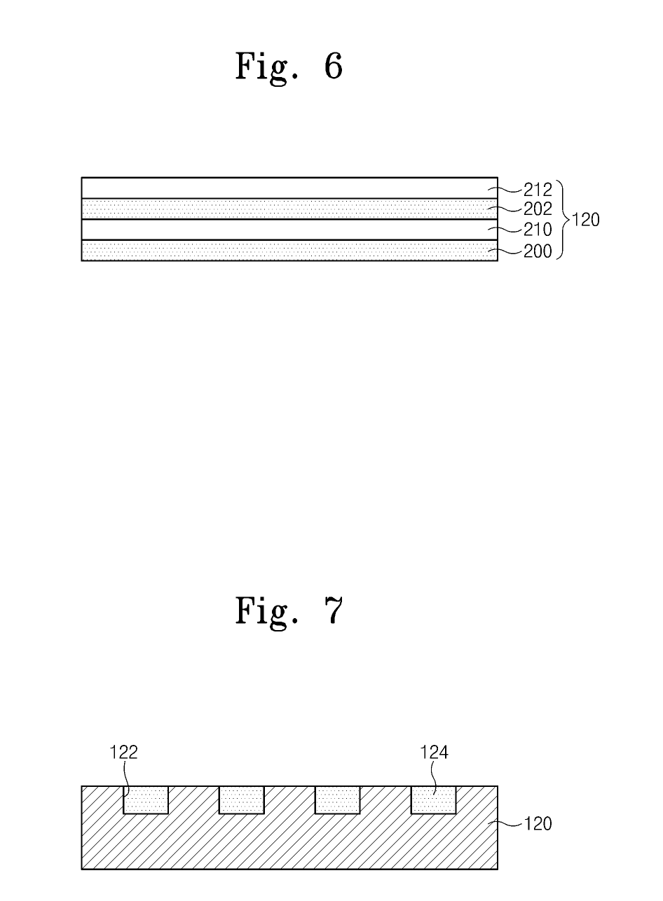

As described above, the selective transparent reflection layer 120 may include a plurality of layers. The plurality of layers may include layers having different refraction indexes that are stacked. A case, in which the selective transparent reflection layer 120 includes a plurality of layers having different refraction indexes, will be described below with reference to FIG. 6.

FIG. 6 is a cross-sectional view illustrating a selective transparent reflection layer according to an embodiment of the present invention.

Referring to FIG. 6, the selective transparent reflection layer 120 may include a plurality of layers 200, 202, 210 and 212. The plurality of layers 200, 202, 210 and 212 may include first selective transparent reflection layers 200 and 202 and second selective transparent reflection layers 210 and 212 which are alternately stacked. The refraction indexes of the first selective transparent reflection layers 200 and 202 and the refraction indexes of the second selective transparent reflection layers 210 and 212 may be different from each other. For example, the refraction indexes of the first selective transparent reflection layers 200 and 202 may be greater than those of the second selective transparent reflection layers 210 and 212. The first selective transparent reflection layer 200 that is most adjacent to the transparent substrate 110 may contact the transparent substrate 110, and the second selective transparent reflection layer 212 that is most adjacent to the first electrode 130 may contact the first electrode 130. The refraction indexes of first selective transparent reflection layers 200 and 202 may be greater than those of the second selective transparent reflection layers 210 and 212. Although two first selective transparent reflection layers and two second selective transparent reflection layers are illustrated in FIG. 6, the first selective transparent reflection layers more than two and the second selective transparent reflection layers more than two may further be disposed. The selective transparent reflection layer 120 includes a plurality of layers having different refraction indexes, and thus a reflection rate for the reflection wavelength region of the selective transparent reflection layer 120 may increase. For example, the amount of infrared rays that are reflected from the selective transparent reflection layer 120 may increase. The reflected infrared rays may be reabsorbed into the photovoltaic conversion layer 132. Accordingly, the photovoltaic energy conversion efficiency of the transparent solar cell can increase.

The selective transparent reflection layer 120 may include a patterned reflection layer having a refraction index that is different from that of the selective transparent reflection layer 120. This will be described below with reference to FIG. 7.

FIG. 7 is a cross-sectional view illustrating a selective transparent reflection layer according to another embodiment of the present invention.

Referring to FIG. 7, the selective transparent reflection layer 120 may include a plurality of grooves 122 at the second surface. By fining distances between adjacent grooves among the plurality of grooves 122, a texturing effect may occur. For example, the distances between the adjacent grooves may be about 300 nm to about 1 mm. A burial selective transparent reflection layer 124 that buries the grooves 122 may be disposed. The burial selective transparent reflection layer 124 may contact the first electrode 130. The refraction index of the burial selective transparent reflection layer 124 may be different from that of the selective transparent reflection layer 120. The minimum refraction index of the selective transparent reflection layer 120 may be greater than the refraction index of the burial selective transparent reflection layer 124. The selective transparent reflection layer 120 and the burial selective transparent reflection layer 124 are interposed between the transparent substrate 110 and the first electrode 130, and thus a reflection rate for a reflection wavelength region may increase. For example, the amount of infrared rays that are reflected from the selective transparent reflection layer 120 may increase. The reflected infrared rays may be reabsorbed into the photovoltaic conversion layer 132. Accordingly, the photovoltaic energy conversion efficiency of the transparent solar cell can increase.

The selective transparent reflection layer 120 may include at least one of aluminum titanium oxide, silicon titanium oxide, aluminum zirconium oxide, zirconium titanium oxide, hafnium titanium oxide, zirconium oxide, titanium oxide, hafnium oxide, aluminum oxide, silicon oxide and nitride silicon oxide.

Light of the transmission wavelength region of the selective transparent reflection layer 120 may be transferred to the transparent substrate 110. The transmission wavelength region may be a visible region. Accordingly, the transparent solar cell may be transparent. The transparent substrate 110 may be formed in a single layer or multi layers. The transparent substrate 110 may include at least one of glass, quartz, transparent organic material and sapphire.

The selective transparent reflection layer 120 according to an embodiment of the present invention may transmit at least a portion of wavelength of the visible rays and reflect infrared rays. Accordingly, the photovoltaic energy conversion efficiency of the transparent solar cell can increase, and the transparent solar cell having high transparency can be provided.

FIG. 2 is a cross-sectional view illustrating a transparent solar cell according to another embodiment of the present invention.

Referring to FIG. 2, as described above, a transparent substrate 110, a selective transparent reflection layer 120, a first electrode 130, a photovoltaic conversion layer 132, a second electrode 138 and a transparent anti-reflection layer 140 may be provided. An addition selective transparent reflection layer 126 may be interposed between the first electrode 130 and the photovoltaic conversion layer 132. An addition transparent anti-reflection layer 142 may be interposed between the photovoltaic conversion layer 132 and the transparent reflection anti-reflection layer 140.

A first plug 131 passing through the addition selective transparent reflection layer 126 may be disposed. The first plug 131 may electrically connect the first electrode 130 and the photovoltaic conversion layer 132. A second plug 139 passing through the addition transparent anti-reflection layer 142 may be disposed. The second plug 139 may electrically connect the photovoltaic conversion layer 132 and the second electrode 138. The first and second plugs 131 and 139 may include the same materials as those of the first and second electrodes 130 and 138.

The refraction index of the transparent anti-reflection layer 140 may be less than that of the second electrode 138. The refraction index of the second electrode 138 may be less than that of the addition transparent anti-reflection layer 142. Accordingly, the amount of light that is reflected from the transparent anti-reflection layer 140, the second electrode 138 and the addition transparent anti-reflection 142 can decrease. Therefore, the amount of light that is incident on the photovoltaic conversion layer 132 can increase, and the photovoltaic energy conversion efficiency of the transparent solar cell can increase.

The refraction index of the addition selective transparent reflection layer 126 may be less than that of the first electrode 130. The refraction index of the first electrode 130 may be less than the minimum refraction index of the selective transparent reflection layer 120. The reflection wavelength regions of the selective transparent reflection layer 120 and the addition selective transparent reflection layer 126 may be infrared regions, and the transmission wavelength regions of the selective transparent reflection layer 120 and the addition selective transparent reflection layer 126 may be visible regions. Comparing with a case of using a single selective transparent reflection layer, transmittance for visible rays may increase and a reflection rate for infrared rays may increase. Accordingly, a transparent solar cell, in which photovoltaic energy conversion efficiency and transparency increase, can be provided. Although two selective transparent reflection layers and two transparent anti-reflection layers are illustrated in the accompanying drawings, a plurality of selective transparent reflection layers and transparent anti-reflection layers may further be interposed.

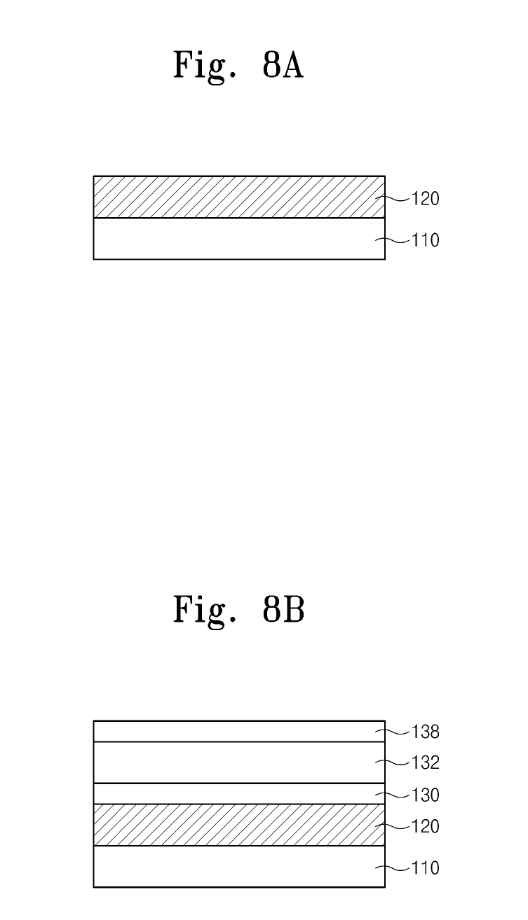

FIGS. 8A and 8B are cross-sectional views illustrating a method for forming a transparent solar cell according to an embodiment of the present invention.

Referring to FIG. 8A, a transparent substrate 110 is provided. A selective transparent reflection layer 120 may be formed on the transparent substrate 110. The selective transparent reflection layer 120 may be formed in any one process that is selected from Atomic Layer Deposition (ALD), Chemical Vapor Deposition (CVD), Physical Vapor Deposition (PVD), Pulse Laser Deposition (PLD) and Sol-Gel processes. In a process for forming the selective transparent reflection layer 120, as described above, the composition ratio of materials constituting the selective transparent reflection layer 120 and the physical thickness of the selective transparent reflection layer 120 may be controlled. In a process for forming the selective transparent reflection layer 120, therefore, the optical thickness of the selective transparent reflection layer 120 may be controlled.

Referring to FIG. 8B, a first electrode 130 may be formed on the selective transparent reflection layer 120. The first electrode 130 may be formed in any one of CVD, PVD and ALD processes. A photovoltaic conversion layer 132 may be formed on the first electrode 130. The photovoltaic conversion layer 132 may include a first conductive layer and a second conductive layer. The first conductive layer may be an N-type layer. At least one of group V elements such as phosphorus (P), arsenic (As) and stibium (Sb) may be injected into the first conductive layer. A thermal treatment process may be performed after the injection of the group V elements. The second conductive layer may be a P-type layer. At least one of group III elements such as boron (B), gallium (Ga) and indium (In) may be injected into the second conductive layer. A thermal treatment process may be performed after the injection of the group III elements. P-N junction may be formed between the first and second conductive layers. On the other hand, before the formation of the second conductive layer, a silicon layer that does not include impurities may be formed on the first conductive layer. A second electrode 138 may be formed on the photovoltaic conversion layer 132. The second electrode 138 may be formed in the same process as a process for forming the first electrode 130.

Returning to FIG. 1, the transparent anti-reflection layer 140 may be formed on the second electrode 138. The transparent anti-reflection layer 140 may be formed in any one process that is selected from ALD, CVD, PVD, PLD and Sol-Gel processes. The light receiving surface of the transparent anti-reflection layer 140 may be textured to have a concave-convex structure. The concave-convex structure may be formed by using any one of a plasma etching process, a mechanical scribing process, a photolithography process and a chemical etching process. As a result, the transparent solar cell of FIG. 1 can be provided.

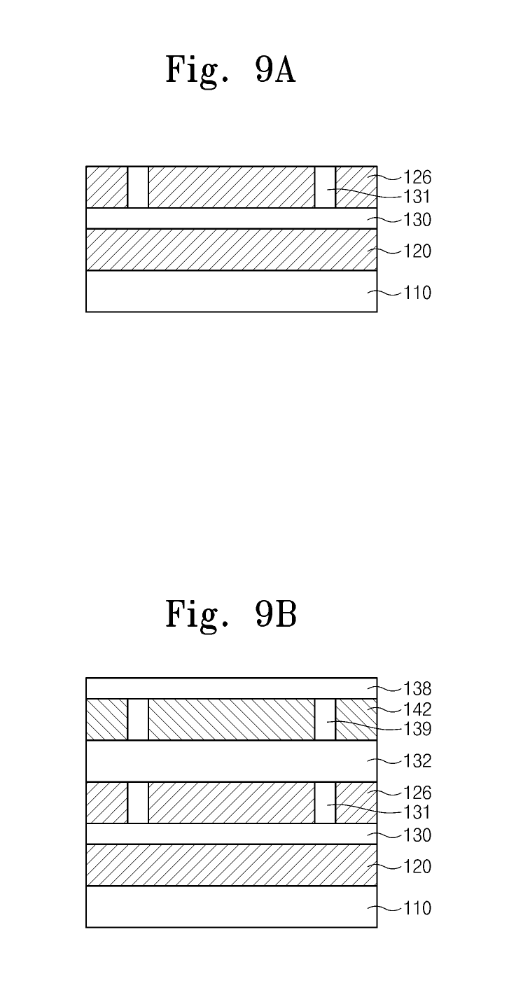

FIGS. 9A and 9B are cross-sectional views illustrating a method for forming a transparent solar cell according to another embodiment of the present invention.

Referring to FIG. 9A, as described above, a transparent substrate 110, a selective transparent reflection layer 120 and a first electrode 130 may be formed. An addition selective transparent reflection layer 126 may be formed on the first electrode 130. The addition selective transparent reflection layer 126 may be formed in the same process as a process for forming the selective transparent reflection layer 120. An opening is formed by etching the addition selective reflection layer 126. The opening may expose the first electrode 130. A first plug 131 that buries the opening may be formed. The first plug 131 may be may be formed in the same process as a process for forming the first electrode 130.

Referring to FIG. 9B, as described above, a photovoltaic conversion layer 132 may be formed on the addition selective transparent reflection layer 126 and the first plug 131. The photovoltaic conversion layer 132 may be electrically connected to the first electrode 130 by the first plug 131. An addition transparent anti-reflection layer 142 may be formed on the photovoltaic conversion layer 132. The addition transparent anti-reflection layer 142 may be formed by using any one of ALD, CVD, PVD, PLD and Sol-Gel processes. An opening may be formed by etching the addition transparent anti-reflection layer 142. The opening may expose the photovoltaic conversion layer 132. A second plug 139 that buries the opening may be formed. The second plug 139 may be formed in the same process as a process for forming the first plug 131. A second electrode 138 may be formed on the addition transparent anti-reflection layer 142 and the second plug 139. The second electrode 138 may be may be formed in the same process as a process for forming the first electrode 130. The second electrode 138 may be electrically connected to the second plug 139 and the photovoltaic conversion layer 132. Returning to FIG. 2, a transparent anti-reflection layer 140 may be formed on the second electrode 138. The transparent anti-reflection layer 140 may be formed in the same process as a process for forming the addition transparent anti-reflection layer 142. Accordingly, the transparent solar cell of FIG. 2 can be provided.

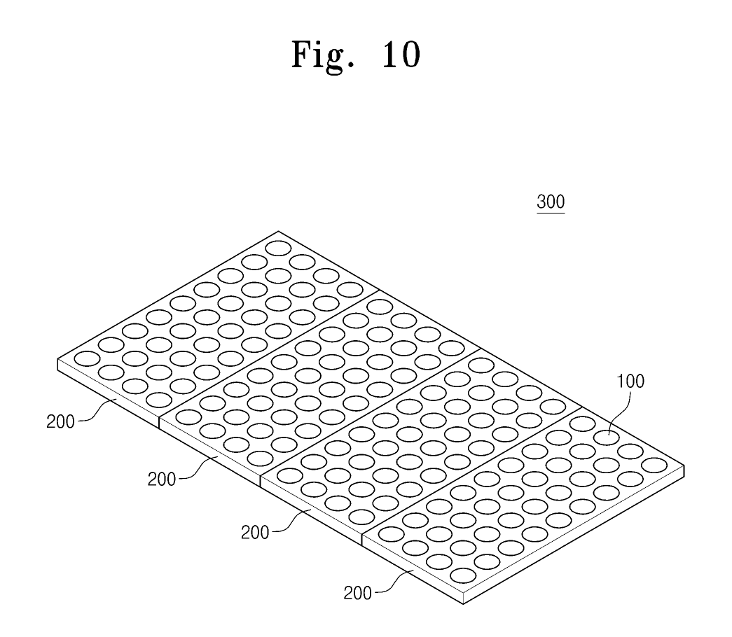

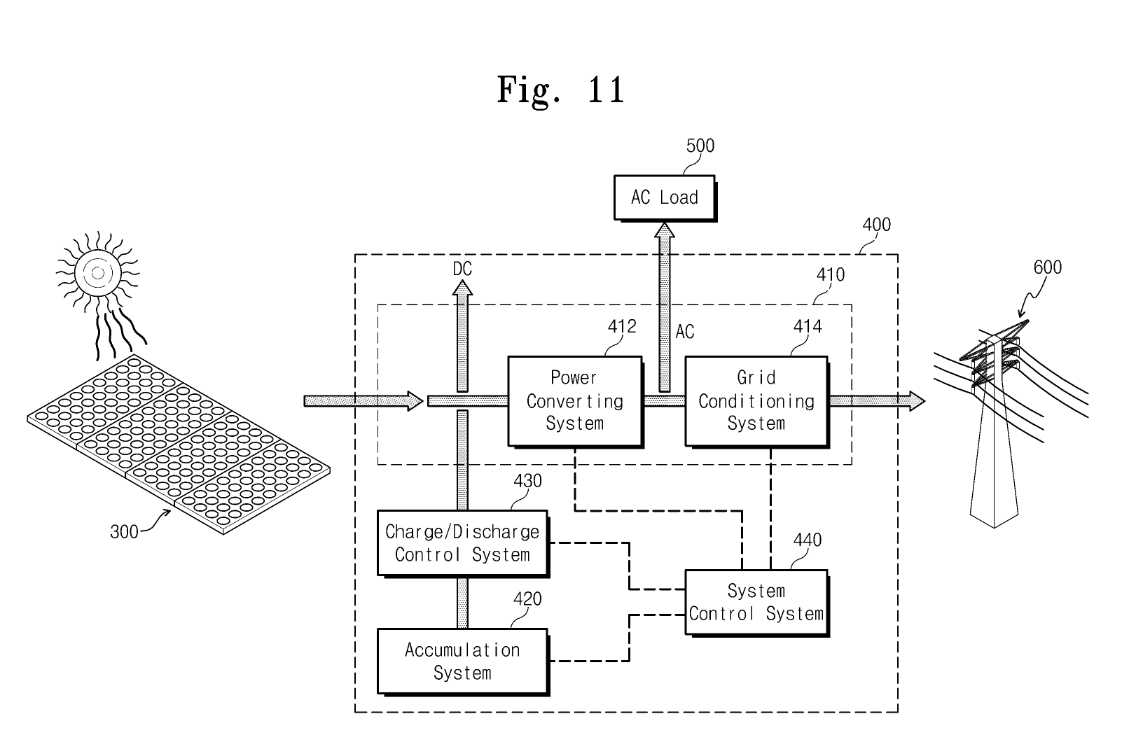

A solar cell array 300 using transparent solar cells according to embodiments of the present invention will be described below with reference to FIG. 10. The solar cell array 300 may be configured by disposing at least one solar cell module 200 at a main frame (not shown). The solar cell modules 200 may be solar cell modules 210, 220 and 230 that have been described above with reference to FIGS. 1 and 2. The solar cell array 300 may be disposed to have a certain angle toward the south for well shining solar light.

The above-described solar cell module or solar cell array may be disposed and used on vehicles, houses, buildings, ships, lighthouses, traffic signal systems, portable electronic devices and various structures. An example of a photovoltaic system with a solar cell according to embodiments of the present invention will be described below with reference to FIG. 11. The photovoltaic system may include the solar cell array 300, and a power control system 400 that receives a power from the solar cell array 300 to supply a power to the outside. The power control system 400 may include an output system 410, an accumulation system 420, a charge/discharge control system 430, and a system control system 440. The output system 410 may include a Power Conditioning System (PCS) 412.

The power conditioning system 412 may be an inverter that inverts a direct current (DC) current from the solar cell array 300 into an alternating current (AC) current. Because solar light does not exist at night and is relatively less shone at a cloudy day, a photovoltaic power may decrease. The accumulation system 420 may store electricity lest a photovoltaic power varies with weather. The charge/discharge control system 430 may store a power from the solar cell array 300 in the accumulation system 420, or may output electricity (which is stored in the accumulation system 420) to the output system 410. The system control system 440 may control the output system 410, the accumulation system 420, and the charge/discharge control system 430.

As described above, the inverted AC current may be supplied to an AC load 500 such as vehicles and homes, thereby being used. Furthermore, the output system 410 may further include a grid connection system 414. The grid connection system 414 may output a power to the outside through the connection of another power grid 600.

Embodiments of the present invention may provide the transparent solar cell, in which infrared rays are not absorbed by the selective transparent reflection layer that reflects rays, and photovoltaic energy conversion efficiency improves by again absorbing the infrared rays that are transmitted.

Embodiments of the present invention may provide the transparent solar cell, which enhances transparency by the selective transparent reflection layer that transmits visible rays of at least one portion of wavelength.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A transparent solar cell, comprising:
a transparent substrate;
a selective transparent reflection layer comprising a first surface contacting the transparent substrate, and a second surface facing the first surface; and
a first electrode, a photovoltaic conversion layer and a second electrode which are sequentially stacked on the second surface of the selective transparent reflection layer,
wherein the selective transparent reflection layer transmits at least a portion of wavelength of a visible ray and reflects an infrared ray.

2. The transparent solar cell of claim 1, further comprising a transparent anti-reflection layer on the second electrode.

3. The transparent solar cell of claim 2, further comprising:
an addition selective transparent reflection layer between the first electrode and the photovoltaic conversion layer;
an addition transparent anti-reflection layer between the second electrode and the photovoltaic conversion layer;
a first plug connecting the first electrode and the photovoltaic conversion layer through the addition selective transparent reflection layer; and
a second plug connecting the second electrode and the photovoltaic conversion layer through the addition transparent anti-reflection layer.

4. The transparent solar cell of claim 3, wherein:
a refraction index of the transparent anti-reflection layer is less than a refraction index of the second electrode,
a refraction index of the second electrode is less than a refraction index of the addition transparent anti-reflection layer,
a refraction index of the addition selective transparent reflection layer is less than a refraction index of the first electrode, and
a refraction index of the first electrode is less than a minimum refraction index of the selective transparent reflection layer.

5. The transparent solar cell of claim 1, wherein a refraction index of the selective transparent reflection layer varies in a direction from the first surface to the second surface.

6. The transparent solar cell of claim 1, wherein a refraction index of the selective transparent reflection layer decreases in a direction from the first surface to the second surface.

7. The transparent solar cell of claim 1, wherein the selective transparent reflection layer comprises a plurality of first and second selective transparent reflection layers which are alternately stacked, and
a refraction index of the first selective transparent reflection layer differs from a refraction index of the second selective transparent reflection layer.

8. The transparent solar cell of claim 7, wherein:
the first selective transparent reflection layer which is most adjacent to the transparent substrate contacts the transparent substrate,
the second selective transparent reflection layer which is most adjacent to the first electrode contacts the first electrode, and
a refraction index of the first selective transparent reflection layer is greater than a refraction index of the second selective transparent reflection layer.

9. The transparent solar cell of claim 1, further comprising a burial selective transparent reflection layer burying a plurality of grooves which are disposed at the second surface of the selective transparent reflection layer.

10. The transparent solar cell of claim 9, wherein a minimum refraction index of the selective transparent reflection layer is greater than a refraction index of the burial selective transparent reflection layer.

11. The transparent solar cell of claim 1, wherein the photovoltaic conversion layer comprises a fine crystal silicon layer.

12. The transparent solar cell of claim 11, wherein the photovoltaic conversion layer further comprises an amorphous silicon layer.

13. The transparent solar cell of claim 1, wherein:
the first electrode comprises resistance-improving materials which are dotted in the first electrode,
the second electrode comprises resistance-improving materials which are dotted in the second electrode, and
a conductivity of the resistance-improving material is greater than conductivities of the first and second electrodes.

14. The transparent solar cell of claim 1, wherein the selective transparent reflection layer and the transparent anti-reflection layer are formed by any one of Atomic Layer Deposition (ALD), Chemical Vapor Deposition (CVD), Physical Vapor Deposition (PVD), Pulse Laser Deposition (PLD) and Sol-Gel processes.

15. The transparent solar cell of claim 1, wherein a transmittance of a visible ray having a first wavelength region of the selective transparent reflection layer is greater than a transmittance of a visible ray having a second wavelength region of the selective transparent reflection layer.

16. The transparent solar cell of claim 1, wherein an optical thickness of the selective transparent reflection layer is about 40 nm to about 10,000 nm.
